(19) United States
(12) Patent Application Publication
(10) Pub. No.: US 2026/0309517 A1
(43) Pub. Date: Oct. 8, 2026

(54) SENSING AND HEATING ARRANGEMENT FOR CAPACITIVE DETECTION OF AN OBJECT

(71) Applicant: IEE INTERNATIONAL ELECTRONICS & ENGINEERING S.A., Echternach (LU)

(72) Inventors: Thomas MEYERS, Wiersdorf (DE); Frank ALTHAUS, Saarbrücken (DE)

(21) Appl. No.: 19/479,952

(22) PCT Filed: Apr. 29, 2024
(86) PCT No.: PCT/EP2024/061763

§ 371 Date: Oct. 29, 2025

(30) Foreign Application Priority Data
May 3, 2023 (LU) LU504120

(51) Int. Cl. G01D 5/24

(52) U.S. Cl. CPC G01D 5/24

(57) ABSTRACT

A sensing and heating arrangement for capacitive detection of an object. The sensing and heating arrangement includes: a heating element, a sensor electrode, a signal generating unit configured to provide a measurement signal to the heating element and the sensor electrode, a first signal sensing circuit including current measuring configured to sense a current flowing through the heating element in response to the measurement signal, and a second signal sensing circuit including current measuring configured to sense a current flowing through the sensor electrode in response to the measurement signal. The heating element and the sensor electrode are configured to generate electric fields in response to the measurement signal, and the sensor electrode and the heating element are at least partially layered on each other.

### TECHNICAL FIELD

The present invention generally relates to a sensing and heating arrangement for capacitive detection of an object, more particularly to a Hands-Off detection sensor for an Advanced Driver Assistance System.

### BACKGROUND

Hands-Off Detection (HOD) sensors are generally used in automotive vehicles to provide information to an Advanced Driver Assistance System (ADAS) regarding the position of the driver hands on the steering wheel. Such HOD can be used to ensure that the driver is in control of the vehicle at all times, which is a fundamental principle of the Vienna Convention on Road Traffic.

HOD sensors typically use a capacitance measurement device comprising two conductive textiles and a grounded steering wheel rim. One of the conductive textiles is layered around the steering wheel rim so as to cover it, thereby forming a guard layer. The other conductive textile is then layered around the guard layer without entering in contact with the latter, thereby forming a sense layer. These sense layer and guard layer are typically kept at a predetermined distance from each other by means of a spacer.

An AC signal is applied to the guard layer and to a transimpedance amplifier connected to the sense layer. As an object approaches the sensor, it becomes capacitively coupled with the sense layer, resulting in a measurable shift in the output of the transimpedance amplifier. Conversely, as the guard and sense layers are kept at similar electric potentials, parasitic capacitance between the sense layer and the grounded rim is prevented. In other words, the guard layer capacitively shields the sense layer from the grounded rim, thereby improving the reliability of the capacitance measurement device.

A drawback of such HOD sensors is the manufacturing cost involved when fitting two conductive textiles around the steering wheel rim. A recent solution consists in removing the guard layer altogether and instead configuring a wire-based heater, which is already fitted in the steering wheel to improve the comfort of the driver, as the guard layer. Unfortunately, the shielding capability of the wire-based heater is much lower than that of the conductive textile and may vary with environmental conditions, e.g. temperature and humidity. Such variations of shielding capability are detrimental to the performance HOD sensors, which must be reliable regardless of environmental conditions.

### SUMMARY

It is therefore desirable to provide a sensing and heating arrangement without the above described shortcomings, which is able to reliably detect the presence of an object regardless of its environmental conditions.

This object is achieved by the sensing and heating arrangement according to claim 1.

The invention provides a sensing and heating arrangement for capacitive detection of an object, comprising:
a heating element,
a sensor electrode,
a signal generating unit configured to provide a measurement signal to the heating element and the sensor electrode,
a first signal sensing circuit including a first current measuring means configured to sense a current flowing into the heating element in response to the measurement signal,
a second signal sensing circuit including a second current measuring means configured to sense a current flowing into the sensor electrode in response to the measurement signal.

The sensor electrode and the heating element are at least partially layered on each other and configured to generate electric fields in response to the measurement signal so that both heater and electrode are operated in the so-called loading mode whilst measurements are performed. In other words, the sensor electrode and the heating element each perform an individual capacitance measurement.

In operation, as sensing arrangement, an AC measurement signal is applied to both the heating element and the sensor electrode, and the electrical currents flowing into the heating element and the sensor electrode are determined by the respective signal sensing circuits. Based on the detected currents, the capacitance between the sensing and heating arrangement and the environment may be determined and the presence of an object such as a hand on the sensor may be determined. It is noted that the same measurement signal is applied to both signal sensing circuits. Hence, the two signal sensing circuits have the same potential, and the capacitance between them is null or extremely low.

Advantageously, using two signal sensing circuits enables to compensate for temperature and humidity variations, thereby increasing the reliability of the measurements. In particular, capacitance measurement values for the heating element and the sensor electrode may be combined, e.g. by subtracting one from the other, to cancel out parasitic capacitance enabled by a decrease in shielding capability due to variations of environmental conditions.

Preferably, the sensing and heating arrangement further comprises a decoupling circuit arranged between the heating element and a power source so as to selectively connect or disconnect the heating element from the power source. The decoupling circuit preferably includes a pair of high and low side switches and/or a common mode choke.

The first and second signal sensing circuits may be configured to sense respective currents flowing into the heating element and the sensor electrode simultaneously or sequentially.

In embodiments, the first and second current measuring means are respectively connected to the heating element and the sensor electrode. The first and/or second current measuring means preferably include a transimpedance amplifier.

In embodiments, a spacer is configured to separate and isolate the heating element and the sensor electrode electrically. The spacer is preferably layered between the heating element and the sensor electrode.

In embodiments, the sensing and heating arrangement is divided in a plurality of zones, such that at least one zone of the plurality of zones is not covered by the sensor electrode, and wherein zones not covered by the sensor electrode are covered by the heating element. Hence, zones of the grounded structure requiring a high degree of robustness may be covered by both the sensor electrode and the heating element, whilst zones requiring a lower degree of robustness may use exclusively the heating element as sensor, thereby saving costs.

The invention further provides a steering wheel with a grounded steering wheel rim and the sensing and heating arrangement according to the above, the latter being mounted around the grounded steering wheel rim to cover at least partially cover the rim.

In embodiments, the sensing and heating arrangement is divided in a front left zone, a front right zone and a back zone. In such an embodiment, the front left and right zones are directed towards a vehicle driver when the sensing and heating arrangement is mounted on the steering wheel, while the back zone faces away from the driver. The sensor electrode may be configured to not cover the back zone, in which case the heating element may be configured to cover the back zone.

The invention further provides a method for capacitive detection of the proximity of an object using the above sensing and heating arrangement comprising the steps of:
providing a measurement signal to the heating element and the sensor electrode;
measuring a quantity related to a capacitance from the sensor electrode;
measuring a quantity related to a capacitance from the heating element;
computing an estimate of the capacitance between the sensor electrode and the object to detect and/or of the capacitance between the heating element and the object to detect based on a difference between quantities derived from the two previous steps.
sending the capacitance estimate of the previous step to an Advanced Driver Assistance System.

An alternative method for capacitive detection of the proximity of an object using the above sensing and heating arrangement comprises the steps of:
providing a measurement signal to the heating element and the sensor electrode.
measuring a quantity related to a capacitance from the heating element or from the sensor element
measuring a quantity related to a capacitance between the sensor electrode and the heating element
computing an estimate of the capacitance between the sensor electrode and the object to detect and/or of the capacitance between the heating element and the object to detect based on a difference between quantities derived from the two previous steps.
sending the capacitance estimate of the previous step to an Advanced Driver Assistance System.

The capacitance measurements from the sensor electrode and the heating element may be performed simultaneously or sequentially.

### BRIEF DESCRIPTION OF THE DRAWINGS

Further details and advantages of the present invention will be apparent from the following detailed description of not limiting embodiments with reference to the attached drawing, wherein:

FIGS. 1a and 1b show diagrams of sensing and heating arrangements in HOD sensors according to prior art designs;

FIGS. 2a and 2b show diagrams of sensing and heating arrangements in HOD sensors according to embodiments of the invention; and

FIGS. 3a and 3b show a representation of capacitive couplings between different components of sensing and heating arrangements.

### DETAILED DESCRIPTION

FIGS. 1a and 1b show diagrams of sensing and heating arrangements 9 according to prior art designs. The sensing and heating arrangement 9 of FIG. 1a comprises a sensor electrode 12 layered around a guard electrode 14. The sensing and heating arrangement itself is mounted around a grounded rim 16, typically a steering wheel rim 16. The steering wheel rim 16 serves as the structural skeleton of a steering wheel (not represented) inside of which the sensing and heating arrangement 9 is fitted. The sensor 12 and guard 14 electrodes may be e.g. conductive textiles or printed electrodes on a flexible insulating substrate. A spacer 18 is arranged between the sensor 12 and guard 14 electrodes, such that a predetermined gap exists between the two and the sensor 12 and guard 14 electrodes are electrically isolated from each other. A heating element 20, typically a wire-based heater, is layered between the guard electrode 14 and the steering wheel rim 16. A power source (not represented) is configured to apply a direct current to the heating element (20) to warm the steering wheel and improve the comfort of the driver.

A signal generating unit 22 is configured to apply an AC signal onto the guard electrode 14 and a transimpedance amplifier 24 connected to the sensor electrode 12. When an object to be detected, i.e. the driver's hands, approaches the sensor electrode 12, the two become capacitively coupled, resulting in a measurable shift in the output of the transimpedance amplifier 24. Variations of the output of the transimpedance amplifier 24 can thus be used to determined whether or not the driver's hands are on the steering wheel.

As the guard 14 and sensor 12 electrodes are kept at similar electric potentials, parasitic capacitance between the sensor electrode 12 and the steering wheel rim 16 is prevented. Indeed, the guard electrode capacitively shields the sensor electrode from the grounded rim 16, such that detection of an object is not affected by the proximity of the sensor electrode to the grounded rim 16.

In other designs, as shown on FIG. 1b, the heating element 20 is layered around the steering wheel rim 16 and configured as guarding electrode. More specifically, the sensing and heating arrangement 9 comprises a single conductive textile or printed electrode configured as sensor electrode 12, and the signal generating unit 22 is configured to apply an AC signal to the heating element 20 and to the transimpedance amplifier 24 connected to the sensor electrode 12. A heating decoupler 26 is arranged to selectively connect or disconnect the heating element 20 from its power source. For example, the heating decoupler 26 may comprise a high side switch arranged between the power source and the heating element 20, and a low side switch arranged between the heating element 20 and ground. The high and low side switches may then be opened during capacitance measurement to set the heating element 20 to a guard state, in which the heating element 20 is kept at the same electric potential as the sensor electrode 12, and closed to set the heating element 20 in a heating state, in which only direct current is present on the heating element 20. Alternatively, the heating decoupler 26 may include a common mode choke configured to selectively prevent AC signal from the signal generating unit 22 from flowing from the heating element 20 to its power source, whilst enabling flow of direct current.

The heating element 20 and sensor electrode 12 are kept at similar electric potentials, reducing the parasitic capacitance between the sensor electrode 12 and the steering wheel rim 16. However, the density of wire-based heaters is not sufficient to completely prevent capacitive coupling between the sensor electrode 12 and the steering wheel rim 16. In particular, the capacitive shielding capabilities of the heating element 20 may vary with environmental conditions, such as temperature and humidity. These variations may result in inaccurate sensing and are to be avoided.

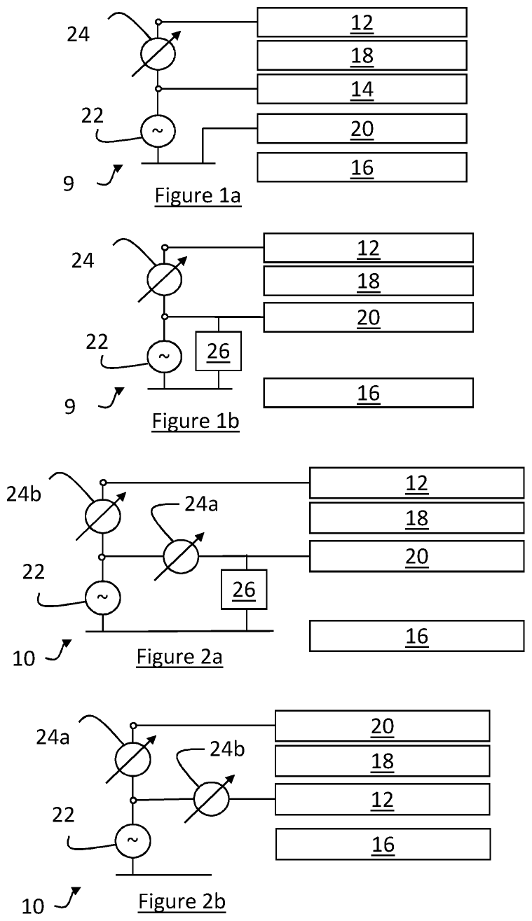

FIGS. 2a and b show diagrams of sensing and heating arrangements 10 according to embodiments of the invention. These sensing and heating arrangements 10 are similar to the one of FIG. 1b and comprise all of its features (the heating decoupler 26 is not represented on FIG. 2b). These sensing and heating arrangements 10 are again mounted around a steering wheel rim 16. However, unlike the design of FIGS. 1a and 1b, both the sensor electrode 12 and the heating element 20 of FIG. 2a are configured as electrodes for capacitive sensing. More particularly, the signal generating unit 22 is configured to apply an AC signal to a first transimpedance amplifier 24a connected to the heating element 20 and to a second transimpedance amplifier 24b connected to the sensor electrode 12. Capacitance measurements from the heating element 20 and from the sensor electrode 12 may be performed simultaneously or alternately or sequentially.

The difference between the sensing and heating arrangements of FIGS. 2a and 2b lies in the order in which the sensor electrode 12 and heating element 20 are layered on one another. In the design of FIG. 2a, the sensor electrode 12 is layered on the heating element 20 such that when the sensing and heating arrangement 10 is mounted around the steering wheel rim 16, the heating element defines an inner layer whilst the sensor electrode 12 defines an outer layer. Conversely, in the design of FIG. 2b, the heating element 20 is layered on the sensor electrode 12 such that when the sensing and heating arrangement 10 is mounted around the steering wheel rim 16, the heating element 20 defines the outer layer whilst the sensor electrode 12 defines the inner layer.

In both embodiments, the inner layer at least partially shields the outer layer from the grounded steering wheel rim 16, and the outer layer at least partially shields the inner layer from the object to detect. As it will be explained below, these designs enable compensation of undesired effects of environmental conditions on the capacitance measurements.

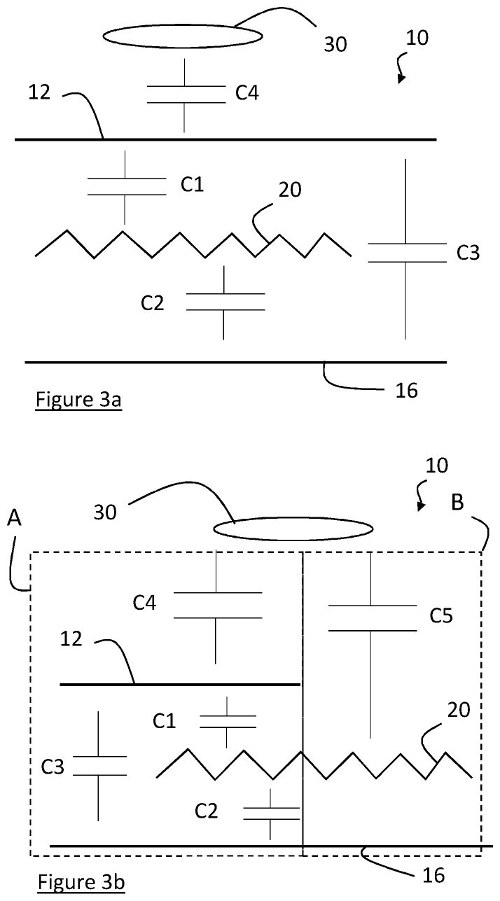

FIGS. 3a and b show a representation of capacitive couplings between different components of a steering wheel implementing sensing and heating arrangements 10 similar to the configuration of FIG. 2a. More specifically, C1 corresponds to the capacitance between the sensor electrode 12 and the heating element 20, C2 corresponds to the capacitance between the heating element 20 and the steering wheel rim 16, C3 corresponds to the capacitance between the sensor electrode 12 and the steering wheel rim 16, and C4 corresponds to the capacitance between the sensor electrode 12 and the object to detect 30. The main quantity of interest is C4, which indicates the presence of the object to detect 30 on the steering wheel.

It is first noted that when the sensor electrode 12 and the heating element 20 have similar electric potential, the capacitance between the two appears to be close to 0 (as no current flows in between), i.e. C1=0. For the same reason, the sensor electrode 12 also capacitively shields the heating element 20 from the object to detect 30. Hence the measured capacitance from the heating element C_{measHeat} can be expressed as C_{measHeat}=C2+C1=C2.

It is further noted that there is a strong correlation between C2 and C3 as both are similarly influenced by the temperature and humidity dependent permittivity of the steering wheel foam. It is thus possible to define a correlation factor α such that C3=α*C2, where a is predefined correlation function or is obtained from a predefined lookup table.

The measured capacitance from the sensor electrode C_{measSense} can be expressed as C_{measSense}=C4+C3, hence C4 can be expressed as

$$C 4 = {C}_{m e a s S e n s e} - C 3 = {C}_{m e a s S e n s e} - α * C 2 \\ C 4 = {C}_{m e a s S e n s e} - α * {C}_{m e a s H e a t}$$

Hence a more accurate estimation of C4 can be obtained from the measured capacitance from the sensor electrode, the measured capacitance from the heating element, and the correction factor α.

Furthermore, when designing a sensing and heating arrangement with multiple zones, the inventive sensing and heating arrangement 10 enables decreasing the number of zones covered by the sensor electrode 12 to reduce costs. The sensor electrode 12 would thus only partially cover the surface of the grounded rim 16. The non-covered area will be exclusively sensed by the heating element instead. Such designs are of particular relevance in applications where zones require different robustness, as in ADAS level 2 and level 3 application. For example, in a 3-zone system with front left, front right and back zone, the sensor electrode 12 could be removed from the back zone, capacitance around the latter being measured exclusively with the heater.

Such a design is represented on FIG. 3b, where region A denotes a zone of the grounded rim 16 covered by both the sensor electrode 12 and the heating element 20, whereas region B denotes a zone of the grounded rim 16 covered only by the heating element 20. C5 corresponds to the capacitance between the heating element and the object to detect.

In this configuration it is assumed that C1 can be measured explicitly, i.e. C1=C_{measSH}. Again, there is a strong correlation between C1, C2 and C3 as all are similarly influenced by the temperature and humidity dependent permittivity of the steering wheel foam. It is thus possible to define a correlation factors β and γ such that C3=β*C1 and C2=γ*C1 where β and γ are predefined correlation function or are obtained from a predefined lookup table.

We thus have for region A:

$${C}_{m e a s S e n s e} = C 4 + C 3 \\ C 4 = {C}_{m e a s S e n s e} - C 3 = {C}_{m e a s S e n s e} - β * C 1 \\ C 4 = {C}_{m e a s S e n s e} - β * {C}_{measSH}$$

And for region B:

$${C}_{m e a s H e a t} = C 5 + C 2 \\ C 5 = {C}_{m e a s H e a t} - C 2 = {C}_{m e a s H e a t} - γ * C 1 \\ C 5 = {C}_{m e a s H e a t} - γ * {C}_{measSH}$$

Therefore, the inventive design enables accurate capacitance measurements in both regions A and B. Whilst this demonstration was performed for steering wheels implementing the configuration of FIG. 2a, the same reasoning can be followed for steering wheels implementing the configuration of FIG. 2b.

1. Sensing and heating arrangement for capacitive detection of an object, comprising:
a heating element;
a sensor electrode; wherein the sensor electrode and the heating element are at least partially layered on each other;
a signal generating unit configured to provide a measurement signal to the heating element and the sensor electrode;
a first signal sensing circuit including a first current measuring means configured to sense a current flowing into the heating element in response to the measurement signal;
a second signal sensing circuit including a second current measuring means configured to sense a current flowing into the sensor electrode in response to the measurement signal;
wherein the sensor electrode and the heating element are configured to generate electric fields in response to the measurement signal.

2. Sensing and heating arrangement according to claim 1, further comprising a decoupling circuit arranged between the heating element and a power source for the heating element so as to selectively connect or disconnect the heating element from the power source.

3. Sensing and heating arrangement according to claim 2, wherein the decoupling circuit includes a pair of high and low side switches and/or a common mode choke.

4. Sensing and heating arrangement according to claim 1, wherein the first and second signal sensing circuits are configured to sense respective currents flowing into the heating element and the sensor electrode simultaneously or sequentially.

5. Sensing and heating arrangement according to claim 1, wherein the first and second current measuring means are respectively connected to the heating element and the sensor electrode, preferably wherein the first and/or second current measuring means include a transimpedance amplifier.

6. Sensing and heating arrangement according to claim 1, further comprising a spacer configured to separate the heating element and the sensor electrode, preferably wherein the spacer is layered between the heating element and the sensor electrode.

7. Sensing and heating arrangement according to claim 1, the sensing and heating arrangement being divided in a plurality of zones, such that at least one zone of the plurality of zones is not covered by the sensor electrode, and wherein a zone not covered by the sensor electrode is covered by the heating element.

8. Steering wheel comprising a grounded steering wheel rim and the sensing and heating arrangement according to claim 1, wherein the sensing and heating arrangement is mounted around the grounded steering wheel rim to at least partially cover the steering wheel rim.

9. Steering wheel according to claim 8, wherein the sensing and heating arrangement is divided in a front left zone, a front right zone and a back zone, and wherein the sensor electrode is configured to not cover the back zone, and wherein the heating element is configured to cover the back zone.

10. Method for capacitive detection of the proximity of an object using the sensing and heating arrangement according to claim 1, comprising the steps of:
providing a measurement signal to the heating element and the sensor electrode;
measuring a quantity related to a capacitance from the sensor electrode;
measuring a quantity related to a capacitance from the heating element;
computing an estimate of the capacitance between the sensor electrode and the object and/or of the capacitance between the heating element and the object based on a difference between quantities derived from the two measuring steps.

11. Method for capacitive detection of the proximity of an object using the sensing and heating arrangement according to claim 1, comprising the steps of:
providing a measurement signal to the heating element and the sensor electrode;
measuring a quantity related to a capacitance from the heating element or from the sensor electrode;
measuring a quantity related to a capacitance between the sensor electrode and the heating element;
computing an estimate of the capacitance between the sensor electrode and the object and/or of the capacitance between the heating element and the object based on a difference between quantities derived from the two measuring steps.

12. Method for capacitive detection of the proximity of an object according to claim 10, wherein the capacitance measurements from the sensor electrode and the heating element are performed simultaneously or sequentially.

13. Method for capacitive detection of the proximity of an object according to claim 10, wherein the measured quantities and/or other quantities derived therefrom are sent to an Advanced Driver Assistance System.

14. Method for capacitive detection of the proximity of an object according to claim 13, wherein the capacitance estimate is sent to the Advanced Driver Assistance System.
